(19) United States
(12) Patent Application Publication
(10) Pub. No.: US 2026/0343741 A1
(43) Pub. Date: Oct. 29, 2026

(54) PRINTED CIRCUIT BOARD, METHOD OF MANUFACTURING THE SAME AND ELECTRONIC COMPONENT PACKAGE INCLUDING THE SAME

(71) Applicant: SAMSUNG ELECTRO-MECHANICS CO., LTD., Suwon-si (KR)

(72) Inventors: Myeonghui JUNG, Suwon-si (KR); Youngil CHO, Suwon-si (KR); Kyunho BAE, Suwon-si (KR); Sanghoon KIM, Suwon-si (KR)

(73) Assignee: SAMSUNG ELECTRO-MECHANICS CO., LTD., Suwon-si, Gyeonggi-do (KR)

(21) Appl. No.: 19/453,454

(22) Filed: Jan. 20, 2026

(30) Foreign Application Priority Data
Apr. 28, 2025 (KR) 10-2025-0055368
Oct. 15, 2025 (KR) 10-2025-0148873

(51) Int. Cl. H05K 1/11; H05K 3/40

(52) U.S. Cl. CPC H05K 1/113; H05K 3/4007; H05K 2201/0939

(57) ABSTRACT

A printed circuit board of the present disclosure may include an insulating layer, a first pad having a side surface embedded in the insulating layer, a first metal layer disposed on the first pad, and a second metal layer disposed on the first metal layer and including a material different from the first metal layer.

### CROSS-REFERENCE TO RELATED APPLICATION

This application claims priority to and the benefit of Korean Patent Application No. 10-2025-0055368 filed with the Korean Intellectual Property Office on Apr. 28, 2025, and Korean Patent Application No. 10-2025-0148873 filed with the Korean Intellectual Property Office on Oct. 15, 2025, the entire contents of which are incorporated herein by reference.

### BACKGROUND

The present disclosure relates to a printed circuit board, a method of manufacturing the same, and an electronic component package including the same.

Printed circuit boards may be used as boards for mounting electronic components.

With the recent development of 3G, 4G, 5G, and more high-speed communication and artificial intelligence (AI) technologies, highly integrated printed circuit boards that implement related electronic components can be used. The electronic components may include a semiconductor chip, an antenna, an inductor, a capacitor, a filter, and the like. For example, a plurality of the electronic components are mounted on a single printed circuit board, so that various and complex product functions can be implemented while reducing the mounting space, thereby miniaturizing and thinning the printed circuit board.

As printed circuit boards become smaller and thinner as described above, miniaturization of I/O first pads and circuit patterns included in the printed circuit boards is required. Since printed circuit boards are recently used in fields that require a high level of reliability, it is necessary to provide printed circuit boards with improved structural stability and reliability while including fine circuit patterns and integrated connection structures.

### SUMMARY

An embodiment of the present disclosure provides a printed circuit board with improved reliability and space efficiency.

Another embodiment of the present disclosure provides a method of manufacturing a printed circuit board with improved reliability and space efficiency.

Another embodiment of the present disclosure provides an electronic package with improved reliability and space efficiency.

A printed circuit board according to an example of the present disclosure may include an insulating layer, a first pad having a side surface embedded in the insulating layer, a first metal layer disposed on the first pad, and a second metal layer disposed on the first metal layer and including a material different from the first metal layer.

At least a portion of an upper surface of the first pad may not be embedded in the insulating layer.

The first metal layer may include nickel.

The second metal layer may include copper.

The first pad and the first metal layer may include different materials.

The printed circuit board may further include a first circuit wiring disposed at substantially the same level as the first pad and having a side surface embedded in the insulating layer, and a solder resist layer disposed on the insulating layer and exposing at least a portion of a side surface and an upper surface of the second metal layer.

The insulating layer may include a first surface and a second surface opposing each other. An upper surface of the first circuit wiring may be disposed at substantially the same level as the first surface of the insulating layer.

The insulating layer may include a first surface and a second surface opposing each other. In a thickness direction perpendicular to the first surface of the insulating layer, a length from an upper surface of the first circuit wiring to an upper surface of the solder resist layer may be greater than a length from an upper surface of the first pad to the upper surface of the second metal layer.

The solder resist layer may include a first region and a second region having a thickness smaller than that of the first region. The first region may cover an upper surface of the first circuit wiring, and the second region may expose at least the portion of the side surface and the upper surface of the second metal layer.

The second region may further expose at least a portion of a side surface of the first metal layer.

The solder resist layer may expose a side surface of the first metal layer and the side surface of the second metal layer.

The second metal layer may include a recess region having a width smaller than each of a width of an upper surface of the second metal layer and a width of a lower surface of the second metal layer.

An electronic component package according to an example of the present disclosure may include an insulating layer, a first pad having a side surface embedded in the insulating layer, a first metal layer disposed on the first pad, a second metal layer disposed on the first metal layer and including a material different from the first metal layer, and an electronic component connected to the second metal layer.

The first metal layer may include nickel, and the second metal layer may include copper.

The second metal layer may include a recess region having a width smaller than each of a width of an upper surface of the second metal layer and a width of a lower surface of the second metal layer.

A method of manufacturing a printed circuit board according to an example of the present disclosure may include forming a dummy pattern on a carrier substrate, forming a first layer including a material different from the dummy pattern on the carrier substrate and the dummy pattern, forming a second layer including a material different from the first layer on the first layer, forming a first wiring layer including a first pad and a first circuit wiring on the second layer, forming a build-up structure including an insulating layer and an additional wiring layer on the second layer and the first wiring layer, removing the carrier substrate, etching the first layer using the dummy pattern and the second layer as an etching barrier to form a second metal layer disposed between the dummy pattern and the second layer, and etching the second layer and the dummy pattern to expose an upper surface of the first circuit wiring and to form a first metal layer disposed between the second metal layer and the first pad.

A width of the dummy pattern may be substantially the same as a width of the first pad.

The second metal layer may include a recess region having a width smaller than each of a width of an upper surface of the second metal layer and a width of a lower surface of the second metal layer.

The method of manufacturing a printed circuit board may further include forming a solder resist layer covering the first circuit wiring and exposing at least a portion of a side surface and an upper surface of the second metal layer on the insulating layer.

The forming of the solder resist layer may include forming a preliminary solder resist layer to cover the first circuit wiring and the second metal layer and thinning a portion of the preliminary solder resist layer to expose at least the portion of the side surface and the upper surface of the second metal layer.

According to an example of the present disclosure, thickness dispersion of each metal layer may be uniformized, roughness may be reduced, and stability and reliability of a printed circuit board may be improved.

According to an example of the present disclosure, the consistency of a protruding pattern and an outermost pad may be improved, and a structural stability and reliability of a printed circuit board may be further improved.

However, the problems to be solved by the embodiments are not limited to those described above and can be variously extended within the scope of the technical ideas included in the embodiments.

### BRIEF DESCRIPTION OF THE DRAWINGS

FIG. 1 is a perspective view schematically illustrating a printed circuit board according to an example.

FIG. 2 is a schematic cross-sectional view of a printed circuit board according to an example taken along line I-I' of FIG. 1.

FIG. 3 is a schematic partially enlarged cross-sectional view of the region A of FIG. 2.

FIG. 4 is a schematic cross-sectional view of a printed circuit board according to another example taken along line I-I' of FIG. 1.

FIG. 5 is a schematic cross-sectional view of a printed circuit board according to another example taken along line I-I' of FIG. 1.

FIGS. 6-20 are cross-sectional views schematically illustrating a method of manufacturing a printed circuit board according to an example.

FIG. 21 is a cross-sectional view schematically illustrating an electronic component package according to an example.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification. In addition, some components in the drawings may be exaggerated, omitted, or schematically illustrated, and the size of each component may not entirely reflect the actual size.

The accompanying drawings are provided only in order to allow embodiments disclosed in the present specification to be easily understood and are not to be interpreted as limiting the concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

It will be further understood that terms "comprises/includes” or “have” used throughout the specification specify the presence of stated features, numerals, steps, operations, components, parts, or a combination thereof, but do not preclude the presence or addition of one or more other features, numerals, steps, operations, components, parts, or a combination thereof. Accordingly, unless explicitly described to the contrary, the word “comprise” and variations such as “comprises” or “comprising” will be understood to imply the inclusion of stated components but not the exclusion of any other components.

Furthermore, throughout the specification, the phrase “in a plan view” means when an object portion is viewed from above, and the phrase “in a cross-sectional view” means when a cross-section taken by vertically cutting an object portion is viewed from the side.

In addition, throughout the specification, "connected" means that two or more components are not only directly connected, but two or more components may be connected indirectly through other components, physically connected as well as being electrically connected, or it may be referred to by different names depending on the location or function but may mean integral.

Hereinafter, embodiments will be described with reference to the drawings.

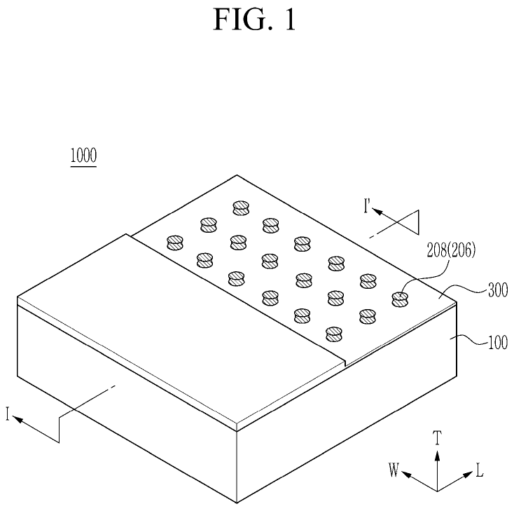

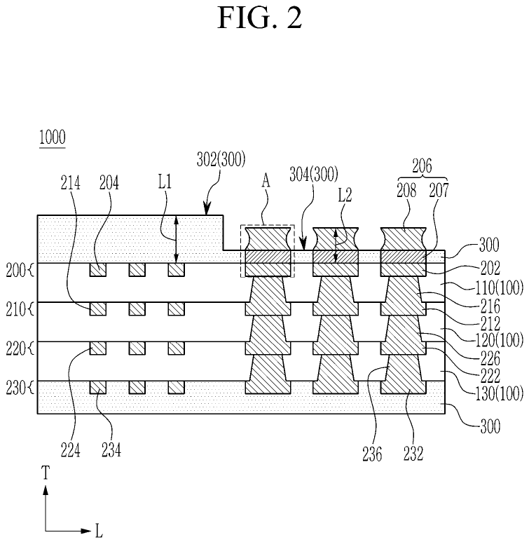

FIG. 1 is a perspective view schematically illustrating a printed circuit board according to an example. FIG. 2 is a schematic cross-sectional view of a printed circuit board according to an example taken along line I-I' of FIG. 1.

The L-axis, W-axis, and T-axis illustrated in the drawings respectively indicate the length direction, width direction, and thickness direction of a printed circuit board 1000 and an insulating layer 100.

The thickness direction (T-axis direction) may indicate a direction substantially perpendicular to a surface of the insulating layer 100. For example, the thickness direction may indicate a direction in which sub-insulating layers 110, 120, and 130 included in the insulating layer 100 are stacked.

Each of the length direction (L-axis direction) and the width direction (W-axis direction) may be approximately parallel to the surface of the insulating layer 100. The length direction and the width direction may be approximately perpendicular to each other on a plane parallel to the surface of the insulating layer 100, and may be approximately perpendicular to the thickness direction, respectively. In an example, a length of the printed circuit board 1000 or the insulating layer 100 in the length direction may be greater than a length in the width direction.

Referring to FIG. 1 and FIG. 2, the printed circuit board 1000 according to an example may include the insulating layer 100, a first pad 202, a first wiring layer 200 including a first circuit wiring 204, and a protruding pattern 206 disposed on the first pad 202. By the protruding pattern 206, a pitch of a bond finger region may be refined, and spatial efficiency of the printed circuit board 1000 may be improved.

The first pad 202 and the first circuit wiring 204 may be disposed on substantially the same layer or at the same level.

The insulating layer 100 may include a plurality of sub-insulating layers 110, 120, and 130. For example, the insulating layer 100 may include a first sub-insulating layer 110, a second sub-insulating layer 120, and a third sub-insulating layer 130 sequentially stacked. An upper surface of the first sub-insulating layer 110 may be provided as a first surface of the insulating layer 100, and a lower surface of the third sub-insulating layer 130 may be provided as a second surface opposing the first surface of the insulating layer 100.

The insulating layer 100 may include an Ajinomoto Build-up Film (ABF). In an example, the insulating layer 100 may include a prepreg manufactured by impregnating glass fibers with a thermosetting resin or a thermoplastic resin. In another example, the insulating layer 100 may include photo-imageable dielectric (PID).

At least a portion of the first wiring layer 200 may be embedded in the first sub-insulating layer 110.

The printed circuit board 1000 may further include a second wiring layer 210 disposed on a lower surface of the first sub-insulating layer 110 and embedded in the second sub-insulating layer 120, a third wiring layer 220 disposed on a lower surface of the second sub-insulating layer 120 and embedded in the third sub-insulating layer 130, and a fourth wiring layer 230 disposed on the lower surface of the third sub-insulating layer 130.

The second wiring layer 210 may include a second pad 212 and a second circuit wiring 214. The third wiring layer 220 may include a third pad 222 and a third circuit wiring 224. The fourth wiring layer 230 may include a fourth pad 232 and a fourth circuit wiring 234.

The second pad 212 and the second circuit wiring 214 may be disposed on substantially the same layer or at the same level. The third pad 222 and the third circuit wiring 224 may be disposed on substantially the same layer or at the same level. The fourth pad 232 and the fourth circuit wiring 234 may be disposed on substantially the same layer or at the same level.

The printed circuit board 1000 may further include a first via 216 penetrating the first sub-insulating layer 110 and connecting the first pad 202 and the second pad 212. The printed circuit board 1000 may further include a second via 226 penetrating the second sub-insulating layer 120 and connecting the second pad 212 to the third pad 222. The printed circuit board 1000 may further include a third via 236 penetrating the third sub-insulating layer 130 and connecting the third pad 222 to the fourth pad 232.

One end of a plurality of the first circuit wirings 204 may be provided as the first pad 202. One end of a plurality of the second circuit wirings 214 may be provided as the second pad 212. One end of a plurality of the third circuit wirings 224 may be provided as the third pad 222. One end of a plurality of the fourth circuit wirings 224 may be provided as the fourth pad 222.

Although the insulating layer 100 is illustrated to include three sub-insulating layers 110, 120, and 130 in FIG. 2, four or more sub-insulating layers may be included depending on the design of the printed circuit board 1000. In this case, circuit wirings and pads may be disposed on each sub-insulating layer, and vias that penetrate the sub-insulating layer and connect pads on different sub-insulating layers may exist.

The printed circuit board 1000 according to the present disclosure may include an embedded trace substrate (ETS) structure.

A side surface of the first pad 202 may be embedded in the insulating layer 100, for example, in the first sub-insulating layer 110. Accordingly, the thickness of the printed circuit board 1000 is reduced, and the area of the pad exposed to the outside is reduced, thereby further improving structural stability. In an example, a side surface of the first circuit wiring 204 may also be embedded in the insulating layer 100.

At least a portion of an upper surface of the first pad 202 may not be embedded in the insulating layer 100. For example, at least a portion of the upper surface of the first pad 202 may be exposed to the first surface of the insulating layer 100.

In an example, an upper surface of the first circuit wiring 204 and the first surface of the insulating layer 100 may be disposed at substantially the same level. Accordingly, the space efficiency of the printed circuit board 1000 may be further improved.

The term "substantially the same" includes mathematical identity, but is not limited thereto, and may include similarities to the extent that the term "substantially the same" is determined to be substantially the same. For example, an upper surface of the first circuit wiring 204 and the first surface of the insulating layer 100 disposed at substantially the same level may mean that a distance in the thickness direction between the upper surface of the first circuit wiring 204 and the first surface of the insulating layer 100 may be less than or equal to about 3μm.

According to an example of the present disclosure, the protruding pattern 206 may include a first metal layer 207 disposed on the first pad 202, and a second metal layer 208 disposed on the first metal layer 207 and including a material different from the first metal layer 207. By sequentially stacking the first metal layer 207 and the second metal layer 208 including different materials, thickness distribution of each metal layer may be uniformized and roughness may be reduced. Accordingly, stability and reliability of the printed circuit board may be improved.

In an example, the first metal layer 207 may include (or be made of) nickel (Ni). The second metal layer 208 may include (or be made of) copper (Cu).

The first pad 202 and the first metal layer 207 may include different materials. Accordingly, etching of the first pad 202 may be prevented and reliability of the printed circuit board 1000 may be improved. In an example, the first pad 202 may include (or be made of) copper (Cu), and the first metal layer 207 may include (or be made of) nickel (Ni).

The first pad 202 and the second metal layer 208 may include (or be made of) the same material. In an example, the first pad 202 and the second metal layer 208 may include (or be made of) copper (Cu).

The wiring layers 200, 210, 220, and 230 described above, the protruding pattern 206, and the vias 216, 226, and 236 may include copper (Cu), aluminum (Al), silver (Ag), tin (Sn), gold (Au), nickel (Ni), lead (Pb), titanium (Ti), alloys thereof, and the like. These may be used alone or in combination of two or more. In an example, the wiring layers 200, 210, 220, and 230 described above, the protruding pattern 206, and the vias 216, 226, and 236 may include (or be made of) copper (Cu).

In an example, the first pad 202 may include (or be made of) copper (Cu), the first metal layer 207 may include (or be made of) nickel (Ni), and the second metal layer 208 may include (or be made of) copper (Cu).

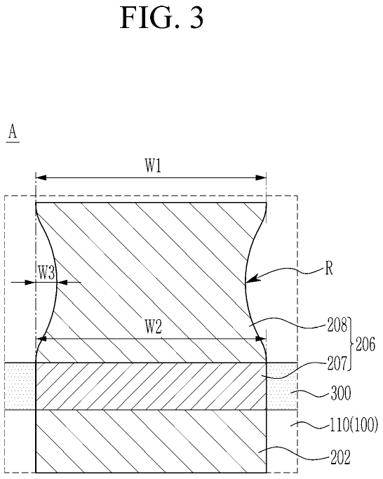

FIG. 3 is a schematic partially enlarged cross-sectional view of the region A of FIG. 2.

Referring to FIG. 3, the second metal layer 208 may include a recess region R having a width smaller than a width W1 of an upper surface of the second metal layer 208 and a width W2 of a lower surface of the second metal layer 208, respectively, in a cross section in which the protruding pattern 206 is cut in the thickness direction so as to pass through the center of an upper surface of the protruding pattern 206, for example, the upper surface of the second metal layer 208. The recess region R may represent a region in which a side surface of the second metal layer 208 is indented toward the center of the second metal layer 208. Stability and reliability may be improved when connecting to an electronic component even in a fine pitch structure by the recess region R.

The recess region R may be disposed between the upper surface and the lower surface of the second metal layer 208.

According to an example, the difference W3, for example, the indented length of the recess region R, between the width W1 of the upper surface of the second metal layer 208 and the minimum width of the recess region R may be about 0.5μm to about 3μm, and in another example, about 1μm to about 2μm. In the above range, while the structural stability of the protruding pattern 206 is maintained or improved, stability and reliability may be improved when connected to an electronic component.

The width W1 of the upper surface of the second metal layer 208 may indicate a length of the longest line segment among line segments connecting two points disposed around the upper surface of the second metal layer 208 and passing through the center point of the upper surface of the second metal layer 208. When the upper surface of the second metal layer 208 is circular, the width W1 of the upper surface of the second metal layer 208 may indicate the diameter of the circle. When the upper surface of the second metal layer 208 is elliptical, the width W1 of the upper surface of the second metal layer 208 may represent a length of a major axis passing through the center point of the ellipse. When the upper surface of the second metal layer 208 has a polygonal shape, the width W1 of the upper surface of the second metal layer 208 may represent the longest diagonal length among the diagonal lines passing through the center point of the polygon.

The width W2 of the lower surface of the second metal layer 208 may indicate the length of the longest line segment among line segments connecting two points located around the lower surface of the second metal layer 208 and passing through the central point of the lower surface of the second metal layer 208. When the lower surface of the second metal layer 208 is circular, a width W2 of the lower surface of the second metal layer 208 may indicate a diameter of the circle. When the lower surface of the second metal layer 208 has an elliptical shape, the width W1 of the lower surface of the second metal layer 208 may indicate the length of a major axis passing through the center point of the ellipse. When the lower surface of the second metal layer 208 has a polygonal shape, the width W2 of the lower surface of the second metal layer 208 may represent the longest diagonal length among the diagonal lines passing through the center point of the polygon.

The W1 and W2 may be measured from a scanning electron microscope (SEM) analysis image of a cross-section (L-T cross-section) cut in the length direction and the thickness direction perpendicular to the width direction of the printed circuit board 1000. In an example, the printed circuit board 1000 may be fixed with an epoxy resin and polished with a polishing machine so that the L-T cross section is exposed. The polishing or the grinding may be performed such that 1/2 of the length of the second metal layer 208 in the width direction is removed. The SEM analysis image may be obtained by performing SEM analysis on the exposed L-T cross section.

Referring again to FIG. 2, the printed circuit board 1000 may further include a solder resist layer 300 disposed on the insulating layer 100. The solder resist layer 300 may expose at least a portion of the side surface and the upper surface of the second metal layer 208. The first circuit wiring 204, which is an outermost circuit wiring, may be protected from external impact or contamination by the solder resist layer 300.

In an example, the solder resist layer 300 may be disposed together on the first surface and the second surface of the insulating layer 100. Accordingly, the outermost circuit wirings 204 and 234 may be protected from external contamination or impact. The solder resist layer 300 disposed on the second surface of the insulating layer 100 may also cover the fourth pad 232.

The solder resist layer 300 may include a known solder resist material, a material including a thermosetting resin, and an inorganic filler. These may be used alone or in combination of two or more.

In the thickness direction, a length L1 from the upper surface of the first circuit wiring 204 to an upper surface of the solder resist layer 300 may be greater than a length L2 from the upper surface of the first pad 202 to the upper surface of the second metal layer 208. As a result, the second metal layer 208 is sufficiently expanded to further improve connectivity with the electronic component, thereby further protecting the first circuit wiring 204 from external contamination and impact.

The L1 and L2 may be measured from SEM analysis images of a cross section (L-T cross section) cut in the length direction and the thickness direction perpendicular to the width direction of the printed circuit board 1000. In an example, the printed circuit board 1000 may be fixed with an epoxy resin and polished with a grinding machine so that the L-T cross section is exposed. The polishing or the grinding may be performed such that 1/2 of the length of the first pad 202 and the second metal layer 208 in the width direction is removed. The SEM analysis image may be obtained by performing SEM analysis on the exposed L-T cross section.

In an example, the solder resist layer 300 may include a first region 302 and a second region 304 having a thickness smaller than that of the first region 302.

The term "thickness" herein may indicate the length in the thickness direction.

The first region 302 may cover the upper surface of the first circuit wiring 204, and the second region 304 may expose at least a portion of the side surface and the upper surface of the second metal layer 208. For example, the second region 304 may be disposed in the bond finger region where the first pad 202 and the protruding pattern 206 are disposed.

In an example, as illustrated in FIG. 2, the second region 304 may cover the entire side surface of the first metal layer 207. In this case, damage or corrosion of the first metal layer 207 may be further suppressed, and reliability of the printed circuit board 1000 may be further improved.

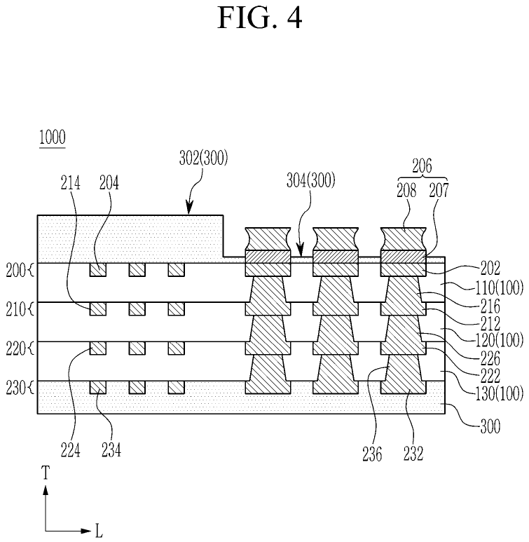

FIG. 4 is a schematic cross-sectional view of a printed circuit board according to another example taken along line I-I' of FIG. 1.

Referring to FIG. 4, in another example of the printed circuit board 1000, the second region 304 may further expose at least a portion of the side surface of the first metal layer 207. In this case, the exposed height of the protruding pattern 206 may increase according to the design of the printed circuit board 1000.

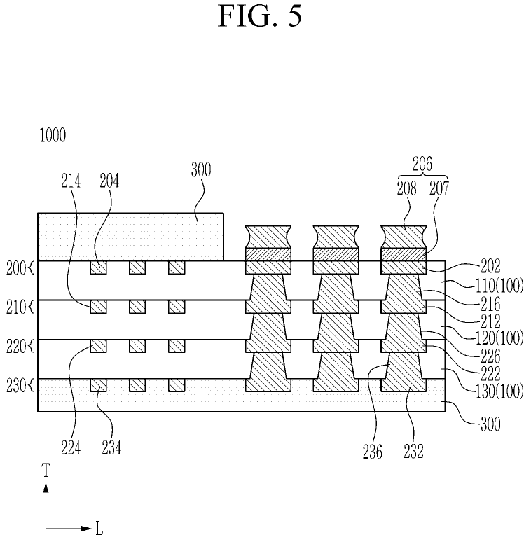

FIG. 5 is a schematic cross-sectional view of a printed circuit board according to another example taken along line I-I' of FIG. 1.

Referring to FIG. 5, the solder resist layer 300 may expose the entire side surface of the protruding pattern 206. For example, the solder resist layer 300 may expose a peripheral area of the first pad 202 and the protruding pattern 206 of the first surface of the insulating layer 100. For example, the solder resist layer 300 of the printed circuit board according to another example may not include the second region described above. In this case, the exposed height of the protruding pattern 206 may be further increased according to the design of the printed circuit board 1000.

In an example, the first surface of the insulating layer 100 to which the protruding pattern 206 is exposed may be a surface facing an electronic component, and the second surface may be a surface facing a mother board on which the printed circuit board 1000 is mounted. In this case, the solder resist layer 300 on the second surface may expose at least a portion of the fourth pad 232.

Hereinafter, a method for manufacturing the printed circuit board 1000 described above will be described with reference to the drawings.

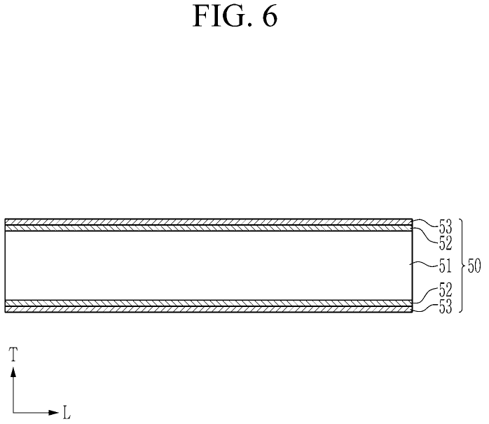

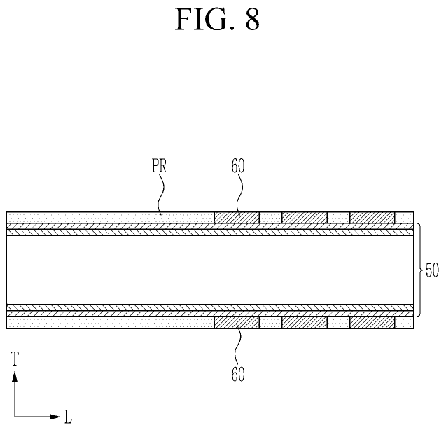

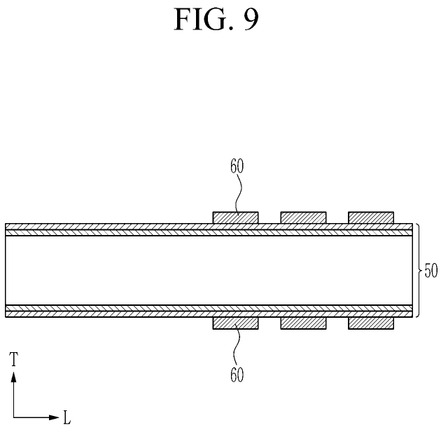

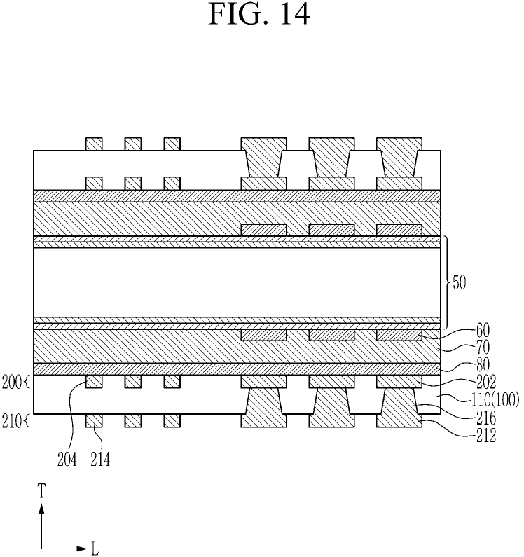

FIGS. 6-20 are cross-sectional views schematically illustrating a method of manufacturing a printed circuit board according to an example.

Referring to FIG. 6, a carrier substrate 50 may be prepared.

The carrier substrate 50 may include a core 51, a release layer 52 disposed on one or both surfaces of the core 51, and a seed metal layer 53 disposed on the release layer 52.

The core 51 may be a detached carrier film and may include, for example, copper clad laminate (CCL) and the like. In this case, the core 51 may include a core layer containing a prepreg manufactured by impregnating glass fibers with thermosetting resin or thermoplastic resin, and a copper foil layer formed on one or both sides of the core layer. The release layer 52 may be disposed on the copper foil layer.

The release layer 52 may be formed using a known material to easily detach the carrier substrate 50.

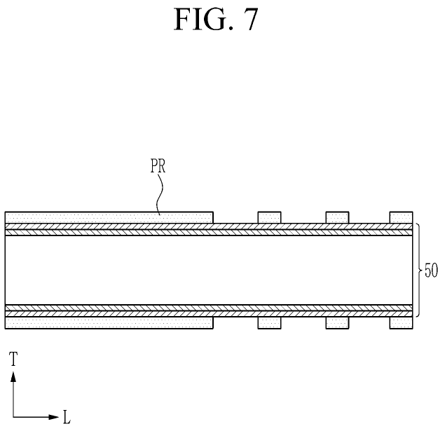

Referring to FIGS. 7-9, a photoresist pattern PR may be formed on one surface or both surfaces of the carrier substrate 50. A dummy pattern 60 may be formed on a portion exposed by the photoresist pattern PR on the carrier substrate 50. For example, the photoresist pattern PR may be provided as a plating mask of the dummy pattern 60. After the dummy pattern 60 is formed, the photoresist pattern PR may be removed.

For example, the dummy pattern 60 may be provided as an etching barrier for forming the protruding pattern 206 described above in an etching process of a first layer to be described later. The dummy pattern 60 may include the same type of material as the first metal layer 207 described above.

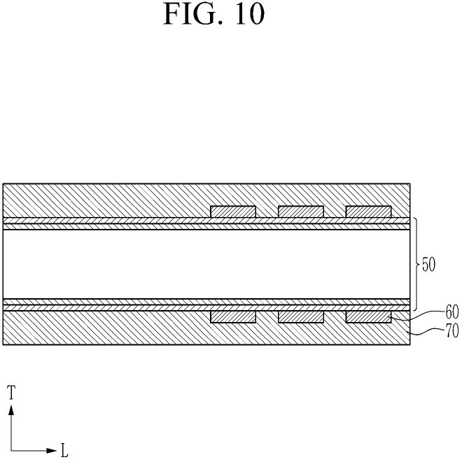

Referring to FIG. 10, the first layer 70 including a material different from that of the dummy pattern 60 may be formed on the carrier substrate 50 and the dummy pattern 60. The first layer 70 may include the same material as the wiring layers 200, 210, 220, and 230 described above. In an example, the dummy pattern 60 may include nickel (Ni) and the first layer 70 may include copper (Cu).

The first layer 70 may be formed through processes such as plating, sputtering, screen printing, evaporation, ink jetting, dispensing, and the like. These may be used alone or in combination of two or more. In an example, the first layer 70 may be formed through a plating process.

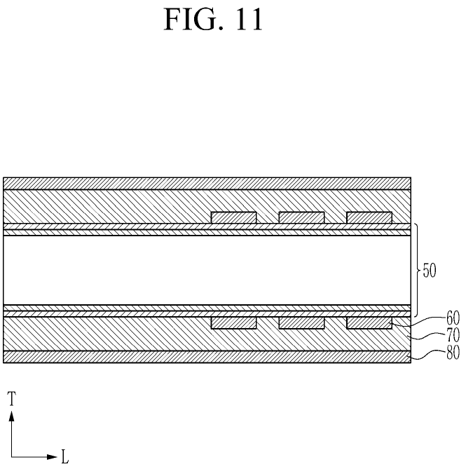

Referring to FIG. 11, a second layer 80 including a material different from that of the first layer 70 may be formed on the first layer 70. In an example, the first layer 70 may include copper (Cu) and the second layer 80 may include nickel (Ni).

The second layer 80 may be formed through processes such as plating, sputtering, screen printing, evaporation, ink jetting, dispensing, and the like. These may be used alone or in combination of two or more. In an example, the second layer 80 may be formed through a plating process.

In an example, the dummy pattern 60 and the second layer 80 may include the same material. For example, each of the dummy pattern 60 and the second layer 80 may include nickel (Ni), and the first layer 70 may include copper (Cu).

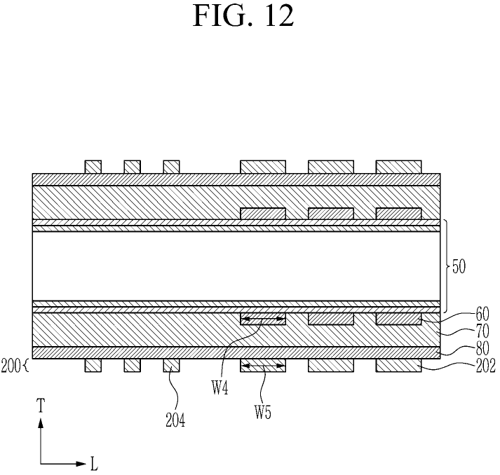

Referring to FIG. 12, the first wiring layer 200 including the first pad 202 and the first circuit wiring 204 may be formed on the second layer 80. For example, a photoresist pattern may be formed on the second layer 80, and the first wiring layer 200 may be plated using the photoresist pattern as a plating mask. After the first wiring layer 200 is formed, the photoresist pattern may be removed.

The first pad 202 may be formed to entirely overlap the dummy pattern 60 in the thickness direction.

According to an example, a width W4 of the dummy pattern 60 and a width W5 of the first pad 202 may be substantially the same. For example, the dummy pattern 60 and the first pad 202 may be formed in substantially the same size using a plating mask (photoresist pattern) with the same specification. In an example, an exposure mask used to expose the photoresist pattern for forming the dummy pattern 60 and an exposure mask used to expose the photoresist pattern for forming the first pad 202 may be the same. Accordingly, the consistency of the protruding pattern 206 and the first pad 202 may be improved, and the structural stability and reliability of the printed circuit board 1000 may be further improved.

The term "substantially the same" includes mathematical identity, but is not limited thereto, and may include similarities to the extent that the term "substantially the same" is determined to be substantially the same. For example, the ratio of the width W5 of the first pad 202 to the width W4 of the dummy pattern 60 may be about 0.9 to 1.1.

The width W4 of the dummy pattern 60 may represent the length of the longest line segment among line segments connecting two points disposed around a surface of the dummy pattern 60 and passing through the center point of the one surface of the dummy pattern 60. When the one surface of the dummy pattern 60 is circular, the width W4 of the dummy pattern 60 may indicate the diameter of the circle. When the one surface of the dummy pattern 60 is elliptical, the width W4 of the dummy pattern 60 may represent a length of a major axis passing through the center point of the ellipse. When the one surface of the dummy pattern 60 has a polygonal shape, the width W4 of the dummy pattern 60 may represent the longest diagonal length among the diagonal lines passing through the center point of the polygon.

The width W5 of the first pad 202 may represent the length of the longest line segment among line segments connecting two points disposed around a surface of the first pad 202 and passing through the center point of the one surface of the first pad 202. When the surface of the first pad 202 is circular, the width W5 of the first pad 202 may indicate the diameter of the circle. When the surface of the first pad 202 is elliptical, the width W5 of the first pad 202 may represent a length of a major axis passing through the center point of the ellipse. When the surface of the first pad 202 has a polygonal shape, the width W5 of the first pad 202 may represent the longest diagonal length among the diagonal lines passing through the center point of the polygon.

The W4 and W5 may be measured from a SEM analysis image of a cross-section (L-T cross-section) cut in the length direction and the thickness direction perpendicular to the width direction of the printed circuit board 1000. In an example, the printed circuit board 1000 may be fixed with an epoxy resin and polished with a polishing machine so that the L-T cross section is exposed. The polishing or the grinding may be performed such that 1/2 of the length of the dummy pattern 60 and the first pad 202 in the width direction is removed. The SEM analysis image may be obtained by performing SEM analysis on the exposed L-T cross section.

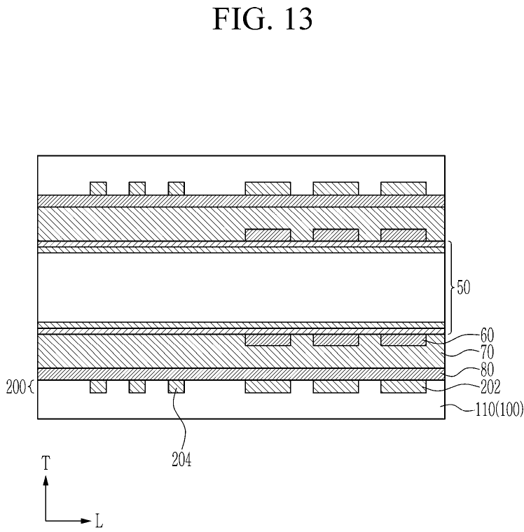

Referring to FIGS. 13-15, a build-up structure BU including the insulating layer 100 and the additional wiring layers 210, 220, and 230 may be formed on the second layer 80 and the first wiring layer 200. The build-up structure BU may further include the vias 216, 226, and 236 penetrating a portion of the insulating layer 100 and connecting pads included in each of the wiring layers 200, 210, 220, and 230.

The wiring layers 200, 210, 220, and 230 and the vias 216, 226, and 236 may be formed through a wiring formation process such as an Additive Process (AP), a Semi AP (SAP), a Modified SAP (MSAP), and a Tenting (TT). These may be used alone or in combination of two or more.

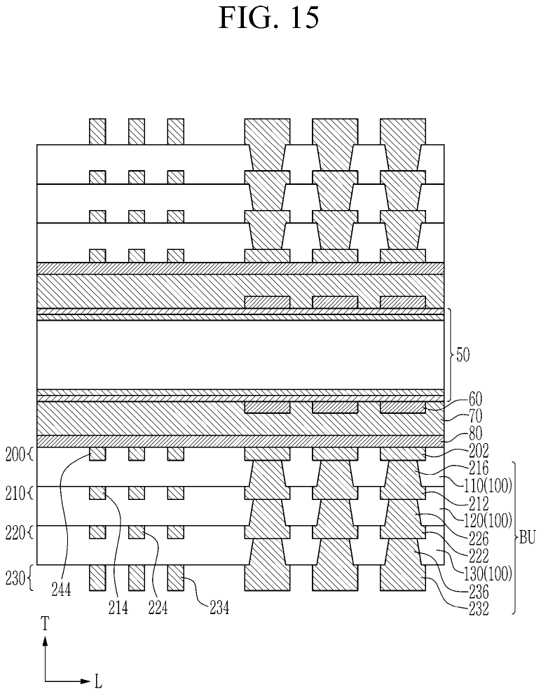

As illustrated in FIG. 15, thicknesses of the fourth pad 232 and the fourth circuit wiring 234 of the fourth wiring layer 230 may be relatively greater than thicknesses of other wiring layers 200, 210, and 220. Accordingly, the fourth wiring layer 230 may have substantially the same or similar thickness as other wiring layers 200, 210, and 220 even when etched together during the etching of the first layer 70 to be described later.

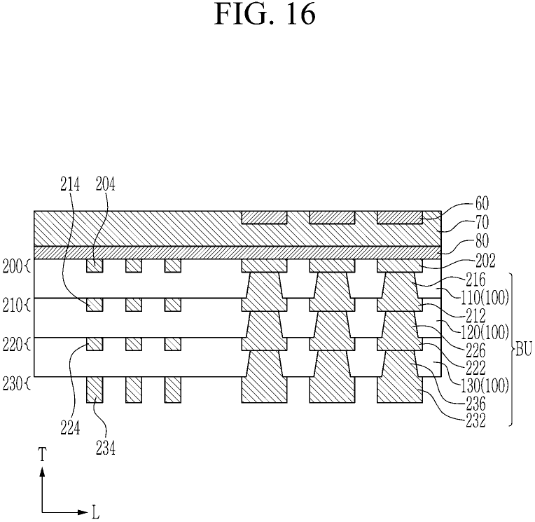

Referring to FIG. 16, the carrier substrate 50 may be removed. For example, the release layer 52 and the seed metal layer 53 may be separated, and the seed metal layer 53 may be removed.

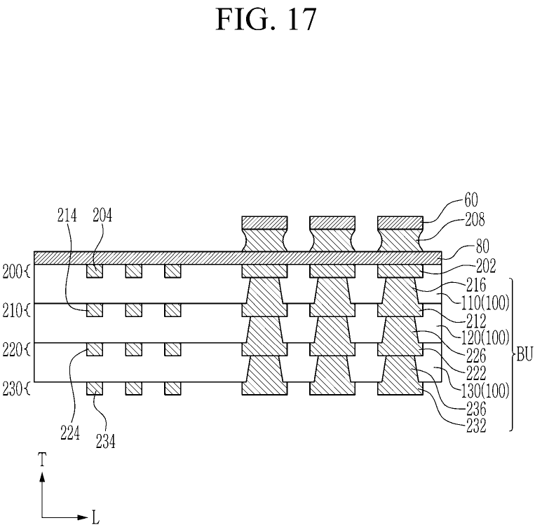

Referring to FIG. 17, the second metal layer 208 may be formed by etching the first layer 70. In this case, the fourth wiring layer 230 may be etched together to have substantially the same or similar thickness as the other wiring layers 200, 210, and 220.

While etching the first layer 70, the dummy pattern 60 including a material different from that of the first layer 70 may be provided as an etching barrier to form the second metal layer 208. In an example, the recess region R may be formed by etching a portion of the side surface of the second metal layer 208.

While etching the first layer 70, the second layer 80 including a material different from that of the first layer 70 is provided as a barrier or a mask, so that damage/etching of the first wiring layer 200 may be suppressed. Accordingly, reliability of the printed circuit board 1000 may be improved.

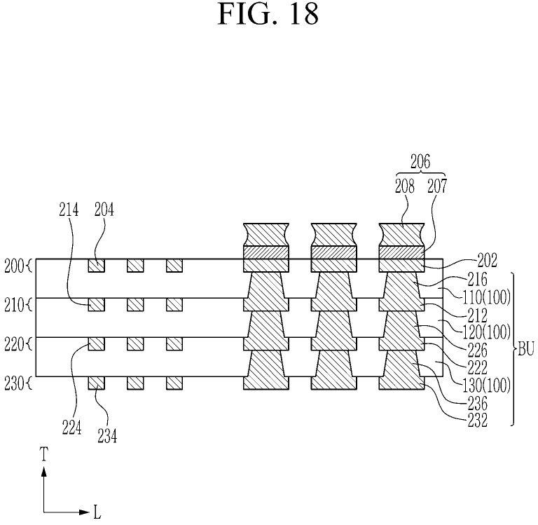

Referring to FIG. 18, the first metal layer 207 of the protruding pattern 206 may be formed by etching the second layer 80 and the dummy pattern 60. The second metal layer 208 including a material different from that of the first metal layer 207 may be provided as a barrier or a mask to form the first metal layer 207.

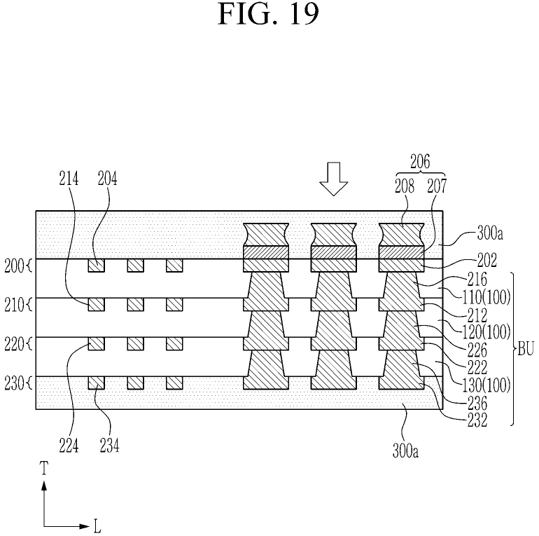

Referring to FIG. 19, a preliminary solder resist layer 300a may be formed on the insulating layer 100 to cover the first circuit wiring 204 and the protruding pattern 206. In an example, the preliminary solder resist layer 300a may entirely cover the first circuit wiring 204 and the protruding pattern 206.

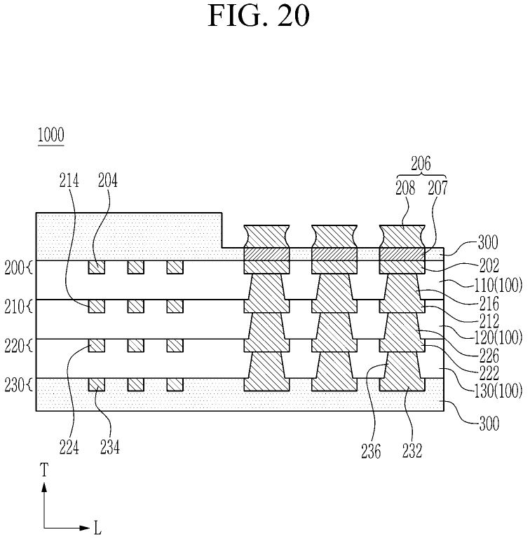

Referring to FIG. 20, the solder resist layer 300 may be formed by thinning a portion of the preliminary solder resist layer 300a to expose the upper surface and at least a portion of the side surface of the protruding pattern 206, for example, the upper surface and at least a portion of the side surface of the second metal layer 208.

The degree/thickness of the thinning may be controlled by controlling the reactivity of a known solder resist etchant. For example, the thinning may be performed so that at least a portion of the side surface of the first metal layer 207 is exposed to form the printed circuit board according to another example schematically illustrated in FIG. 4. The thinning may be performed so that the entire first metal layer 207 is exposed to form the printed circuit board according to another example schematically illustrated in FIG. 5.

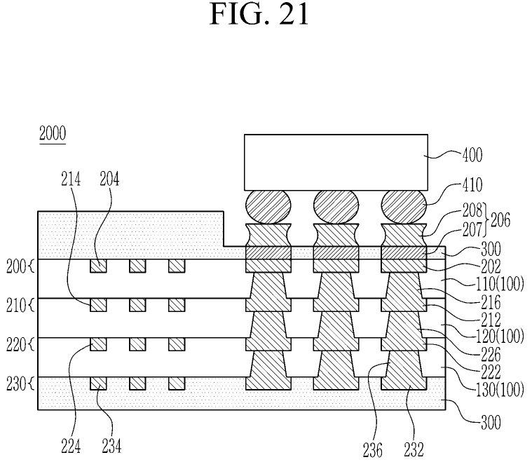

FIG. 21 is a cross-sectional view schematically illustrating an electronic component package according to an example.

Referring to FIG. 21, an electronic component package 2000 according to an example may include the printed circuit board 1000 described above and an electronic component 400 connected to the protruding pattern 206 of the printed circuit board 1000.

In an example, the electronic component package 2000 may further include a solder 410 disposed between the electronic component 400 and the protruding pattern 206 and connecting the electronic component 400 and the protruding pattern 206.

By the protruding pattern 206, a fine pitch may be implemented and connection stability between the electronic component 400 and the printed circuit board 1000 may be improved.

Although preferred embodiments have been described above, this disclosure is not limited thereto, and can be variously modified within the scope of this disclosure, and it is natural that various modifications also fall within the scope of this disclosure.

What is claimed is:

1. A printed circuit board comprising:
an insulating layer;
a first pad having a side surface embedded in the insulating layer;
a first metal layer disposed on the first pad; and
a second metal layer disposed on the first metal layer and comprising a material different from the first metal layer.

2. The printed circuit board of claim 1, wherein
at least a portion of an upper surface of the first pad is not embedded in the insulating layer.

3. The printed circuit board of claim 1, wherein
the first metal layer comprises nickel.

4. The printed circuit board of claim 1, wherein
the second metal layer comprises copper.

5. The printed circuit board of claim 1, wherein
the first pad and the first metal layer comprise different materials.

6. The printed circuit board of claim 1, further comprising
a first circuit wiring disposed at substantially the same level as the first pad and having a side surface embedded in the insulating layer, and
a solder resist layer disposed on the insulating layer and exposing at least a portion of a side surface and an upper surface of the second metal layer.

7. The printed circuit board of claim 6, wherein
the insulating layer comprises a first surface and a second surface opposing each other, and
an upper surface of the first circuit wiring is disposed at substantially the same level as the first surface of the insulating layer.

8. The printed circuit board of claim 6, wherein
the insulating layer comprises a first surface and a second surface opposing each other, and
in a thickness direction perpendicular to the first surface of the insulating layer, a length from an upper surface of the first circuit wiring to an upper surface of the solder resist layer is greater than a length from an upper surface of the first pad to the upper surface of the second metal layer.

9. The printed circuit board of claim 6, wherein
the solder resist layer comprises a first region and a second region having a thickness smaller than that of the first region, and
the first region covers an upper surface of the first circuit wiring, and the second region exposes at least the portion of the side surface and the upper surface of the second metal layer.

10. The printed circuit board of claim 9, wherein
the second region further exposes at least a portion of a side surface of the first metal layer.

11. The printed circuit board of claim 6, wherein
the solder resist layer exposes a side surface of the first metal layer and the side surface of the second metal layer.

12. The printed circuit board of claim 1, wherein
the second metal layer comprises a recess region having a width smaller than each of a width of an upper surface of the second metal layer and a width of a lower surface of the second metal layer.

13. An electronic component package comprising:
an insulating layer;
a first pad having a side surface embedded in the insulating layer;
a first metal layer disposed on the first pad;
a second metal layer disposed on the first metal layer and comprising a material different from the first metal layer; and
an electronic component connected to the second metal layer.

14. The electronic component package of claim 13, wherein
the first metal layer comprises nickel, and the second metal layer comprises copper.

15. The electronic component package of claim 13, wherein
the second metal layer comprises a recess region having a width smaller than each of a width of an upper surface of the second metal layer and a width of a lower surface of the second metal layer.

16. A method of manufacturing a printed circuit board comprising:
forming a dummy pattern on a carrier substrate;
forming a first layer comprising a material different from the dummy pattern on the carrier substrate and the dummy pattern;
forming a second layer comprising a material different from the first layer on the first layer;
forming a first wiring layer comprising a first pad and a first circuit wiring on the second layer;
forming a build-up structure comprising an insulating layer and an additional wiring layer on the second layer and the first wiring layer;
removing the carrier substrate;
etching the first layer using the dummy pattern and the second layer as an etching barrier to form a second metal layer disposed between the dummy pattern and the second layer; and
etching the second layer and the dummy pattern to expose an upper surface of the first circuit wiring and to form a first metal layer disposed between the second metal layer and the first pad.

17. The method of claim 16, wherein
a width of the dummy pattern is substantially the same as a width of the first pad.

18. The method of claim 16, wherein
the second metal layer comprises a recess region having a width smaller than each of a width of an upper surface of the second metal layer and a width of a lower surface of the second metal layer.

19. The method of claim 16, further comprising
forming a solder resist layer covering the first circuit wiring and exposing at least a portion of a side surface and an upper surface of the second metal layer on the insulating layer.

20. The method of claim 19, wherein
the forming of the solder resist layer comprises
forming a preliminary solder resist layer to cover the first circuit wiring and the second metal layer; and
thinning a portion of the preliminary solder resist layer to expose at least the portion of the side surface and the upper surface of the second metal layer.
